(19) United States
(12) Patent Application Publication
(10) Pub. No.: US 2018/0005944 A1
(43) Pub. Date: Jan. 4, 2018

(54) SUBSTRATE WITH SUB-INTERCONNECT LAYER

(71) Applicant: Intel Corporation, Santa Clara, CA (US)

(72) Inventors: Eng Huet Goh, Ayer Itam (MY); Jiun Hann Sir, Gelugor (MY); Min Suet Lim, Bayan Lepas (MY); Khang Choong Yong, Puchong (MY)

(73) Assignee: Intel Corporation, Santa Clara, CA (US)

(21) Appl. No.: 15/201,388

(22) Filed: Jul. 2, 2016

(51) Int. Cl. H01L 23/535; H01L 21/48; H01L 23/498; H01L 23/50

(52) U.S. Cl. CPC H01L 23/535; H01L 23/50; H01L 21/4803; H01L 21/486; H01L 23/49811

(57) ABSTRACT

Electrical interconnect technology for a package substrate is disclosed. A substrate can include a first conductive element at least partially disposed in a first routing layer, and a second conductive element at least partially disposed in a second routing layer. The first and second routing layers are adjacent routing layers. The substrate can also include a third conductive element having first and second portions disposed in the first routing layer, and an intermediate third portion disposed in a “sub-interconnect layer” between the first and second routing layers.

### TECHNICAL FIELD

Embodiments described herein relate generally to electrical interconnect technology, and more particularly to routing signals through a substrate.

### BACKGROUND

A typical package substrate, known as a 6L design, has six routing layers of traces or interconnects (i.e., three trace layers 1FC, 2F, and 3F on a die side of the substrate, and three trace layers 1BC, 2B, and 3B on a land side of the substrate). Typically, the uppermost one or two interconnect layers, such as trace layer 3F and trace layer 2F, are used for routing large numbers of input/output (I/O) signals, memory signals, clocks, strobes, voltage references, etc. (referred to collectively as “signal I/O” for simplicity), while the lower layers are used for providing power, ground, shielding, etc. Signals are routed between trace layers using vias. Similarly, power and ground planes may be routed or coupled between adjacent layers using vias. Interconnect structures, such as solder balls or bumps, are distributed on a flip-chip die and/or the package substrate in a pattern. Some of those bumps are for carrying I/O signals and some are for carrying power and ground signals. Typically, the I/O signals will be connected to other chips on the package substrate and/or a motherboard. Thus, it is desirable to route those signals using the generally outer bumps, and to use the generally inner bumps for power and ground. In some high-density or high-signal-count applications, the I/O signal count and/or the I/O bump density may be such that it is difficult or impossible to route all of the I/O signals on the uppermost trace layer 3F. In such applications, some of the I/O signals are routed on the uppermost trace layer, while other I/O signals are routed from their respective bumps down through vias to a lower trace layer, such as trace layer 2F, and outward to a location where the design rules and physical dimensions permit, then back up through a via to the uppermost trace layer, and from there to their destinations.

### BRIEF DESCRIPTION OF THE DRAWINGS

Invention features and advantages will be apparent from the detailed description which follows, taken in conjunction with the accompanying drawings, which together illustrate, by way of example, various invention embodiments; and, wherein:

FIG. 1 illustrates a schematic cross-section of an electronic device package in accordance with an example;

FIG. 2 illustrates a top view of electrically conductive elements of a substrate of the electronic device package of FIG. 1;

FIG. 3 illustrates a detail view of a substrate of the electronic device package of FIG. 1;

FIG. 4 illustrates a top view of an array of interface features and a trace breakout region in accordance with an example;

FIG. 5A illustrates a dielectric layer disposed on a routing layer that includes an electrically conductive element in accordance with an example of a method for making a substrate;

FIG. 5B illustrates forming a recess in a portion of a dielectric layer in accordance with an example of a method for making a substrate;

FIG. 5C illustrates disposing a conductive material in a recess to form a sub-interconnect portion of an electrically conductive element in accordance with an example of a method for making a substrate;

FIG. 5D illustrates disposing a dielectric material portion at least partially on a sub-interconnect portion of an electrically conductive element in accordance with an example of a method for making a substrate;

FIG. 5E illustrates forming via openings in a dielectric material portion in accordance with an example of a method for making a substrate;

FIG. 5F illustrates forming portions of a conductive element at least partially on a dielectric material portion in accordance with an example of a method for making a substrate;

FIG. 5G illustrates forming a solder resist layer at least partially on a dielectric material portion and/or a conductive element in accordance with an example of a method for making a substrate;

FIG. 5H illustrates disposing interconnect structures on exposed interface features in accordance with an example of a method for making a substrate; and

FIG. 6 is a schematic illustration of an exemplary computing system.

Reference will now be made to the exemplary embodiments illustrated, and specific language will be used herein to describe the same. It will nevertheless be understood that no limitation of the scope or to specific invention embodiments is thereby intended.

### DESCRIPTION OF EMBODIMENTS

Before invention embodiments are disclosed and described, it is to be understood that no limitation to the particular structures, process steps, or materials disclosed herein is intended, but also includes equivalents thereof as would be recognized by those ordinarily skilled in the relevant arts. It should also be understood that terminology employed herein is used for the purpose of describing particular examples only and is not intended to be limiting. The same reference numerals in different drawings represent the same element. Numbers provided in flow charts and processes are provided for clarity in illustrating steps and operations and do not necessarily indicate a particular order or sequence. Unless defined otherwise, all technical and scientific terms used herein have the same meaning as commonly understood by one of ordinary skill in the art to which this disclosure belongs.

As used in this written description, the singular forms “a,” “an” and “the” provide express support for plural referents unless the context clearly dictates otherwise. Thus, for example, reference to “a layer” includes a plurality of such layers.

In this application, “comprises,” “comprising,” “containing” and “having” and the like can have the meaning ascribed to them in U.S. Patent law and can mean “includes,” “including,” and the like, and are generally interpreted to be open ended terms. The terms “consisting of” or “consists of” are closed terms, and include only the components, structures, steps, or the like specifically listed in conjunction with such terms, as well as that which is in accordance with U.S. Patent law. “Consisting essentially of” or “consists essentially of” have the meaning generally ascribed to them by U.S. Patent law. In particular, such terms are generally closed terms, with the exception of allowing inclusion of additional items, materials, components, steps, or elements, that do not materially affect the basic and novel characteristics or function of the item(s) used in connection therewith. For example, trace elements present in a composition, but not affecting the composition's nature or characteristics would be permissible if present under the “consisting essentially of” language, even though not expressly recited in a list of items following such terminology. When using an open ended term in the written description like “comprising” or “including,” it is understood that direct support should be afforded also to “consisting essentially of” language as well as “consisting of” language as if stated explicitly and vice versa.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments described herein are, for example, capable of operation in other orientations than those illustrated or otherwise described herein. The term “coupled,” as used herein, is defined as directly or indirectly connected in an electrical or nonelectrical manner. Objects described herein as being “adjacent to” each other may be in physical contact with each other, in close proximity to each other, or in the same general region or area as each other, as appropriate for the context in which the phrase is used. Occurrences of the phrase “in one embodiment,” or “in one aspect,” herein do not necessarily all refer to the same embodiment or aspect.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, sizes, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually.

This same principle applies to ranges reciting only one numerical value as a minimum or a maximum. Furthermore, such an interpretation should apply regardless of the breadth of the range or the characteristics being described.

Reference throughout this specification to “an example” means that a particular feature, structure, or characteristic described in connection with the example is included in at least one embodiment. Thus, appearances of the phrases “in an example” in various places throughout this specification are not necessarily all referring to the same embodiment.

Furthermore, the described features, structures, or characteristics may be combined in any suitable manner in one or more embodiments. In this description, numerous specific details are provided, such as examples of layouts, distances, network examples, etc. One skilled in the relevant art will recognize, however, that many variations are possible without one or more of the specific details, or with other methods, components, layouts, measurements, etc. In other instances, well-known structures, materials, or operations are not shown or described in detail but are considered well within the scope of the disclosure.

### EXAMPLE EMBODIMENTS

An initial overview of technology embodiments is provided below and specific technology embodiments are then described in further detail. This initial summary is intended to aid readers in understanding the technology more quickly but is not intended to identify key or essential features of the technology nor is it intended to limit the scope of the claimed subject matter.

The trace or interconnect routing in a typical 6L package substrate is effective for high-density signal I/O routing, however, it does have some drawbacks in certain applications. In particular, small form factors are becoming increasingly significant for certain types of electronic devices. The size limitations presented by the thickness of a 6L substrate may be a barrier to further size reduction in many cases. The thickness of a package substrate can be reduced by reducing the number of routing layers, such as to a 4L design (i.e., four routing layers for traces or interconnects, with two layers per side). One way to enable 4L packaging is to modify the bump pitch/pattern to enable single layer breakout. However, this would increase the I/O density on the outer routing layer of the substrate and have a large impact on the overall die size and/or cost. It is therefore desirable to utilize the advantages provided by a bump pattern configured for a 6L design in a relatively thin package substrate, such as a 4L substrate.

Accordingly, a substrate is disclosed that can be a 4L design while supporting a bump pattern configured for a 6L design. In one aspect, the substrate eliminates the need for two layers of breakout in order to support high signal I/O applications. In one example, a substrate in accordance with the present disclosure can include a first conductive element at least partially disposed in a first routing layer, and a second conductive element at least partially disposed in a second routing layer. The first and second routing layers are adjacent routing layers. The substrate can also include a third conductive element having first and second portions disposed in the first routing layer, and an intermediate third portion disposed in a “sub-interconnect layer” between the first and second routing layers.

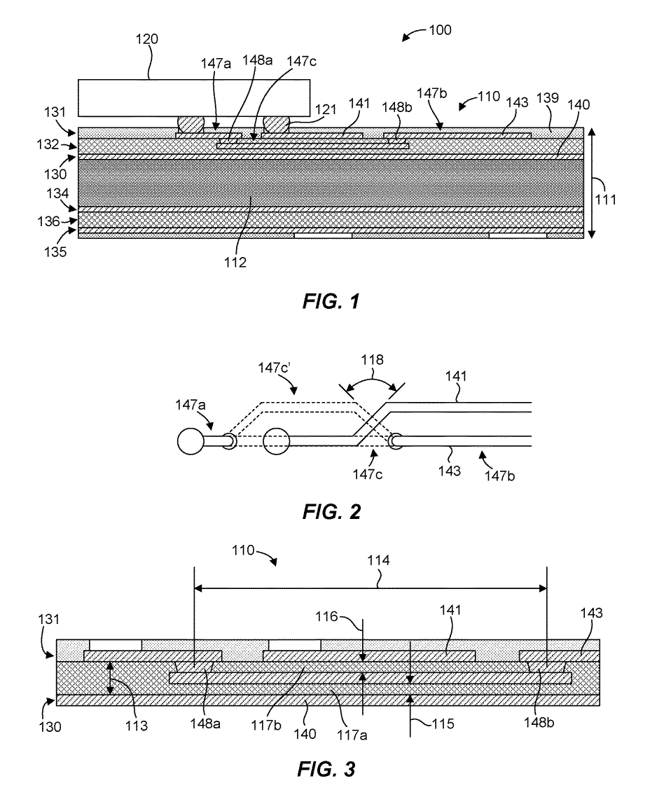

Referring to FIG. 1, an exemplary electronic device package 100 is schematically illustrated in cross-section. The package 100 can include a substrate 110 and an electronic component 120 mounted on or otherwise coupled to the substrate 110. An electronic component can be any electronic device or component that may be included in an electronic device package, such as a semiconductor device (e.g., a die, a chip, a processor, computer memory, platform controller hub, etc.). In one embodiment, the electronic component 120 may represent a discrete chip. The electronic component 120 may be, include, or be a part of a processor, memory, or application specific integrated circuit (ASIC) in some embodiments. Although one electronic component 120 is depicted in FIG. 1, any suitable number of electronic components can be included. The electronic component 120 can be attached to the substrate 110 according to a variety of suitable configurations including a flip-chip configuration, wire bonding, and the like. The electronic component 120 can be electrically coupled to the substrate 110 using interconnect structures 121 (e.g., the illustrated solder balls or bumps and/or wire bonds) configured to route electrical signals between the electronic component 120 and the substrate 110. In some embodiments, the interconnect structures 121 may be configured to route electrical signals such as, for example, I/O signals and/or power or ground signals associated with the operation of the electronic component 120.

In general, the substrate 110 may include electrically conductive elements or electrical routing features configured to route electrical signals to or from the electronic component 120. The electrical routing features may be internal (e.g., disposed at least partially within a thickness 111 of the substrate 110) and/or external to the substrate 110. For example, in some embodiments, the substrate 110 may include electrically conductive elements or electrical routing features such as pads, vias, and/or traces configured to receive the interconnect structures 121 and route electrical signals to or from the electronic component 120. The pads, vias, and traces can be constructed of the same or similar electrically conductive materials (e.g., copper, gold, silver, aluminum, zinc, nickel, brass, bronze, iron, etc.), or of different electrically conductive materials. Electrically conductive elements or electrical routing features of the substrate 110 are discussed in more detail below. The electronic device package 100 can also include interconnects (not shown), such as solder balls, for coupling with another substrate (e.g., a circuit board such as a motherboard) for power and/or signaling.

The substrate 110 may be formed of any suitable semiconductor material (e.g., a silicon, gallium, indium, germanium, or variations or combinations thereof, among other substrates), one or more insulating layers, such as glass-reinforced epoxy, such as FR-4, polytetrafluoroethylene (Teflon), cotton-paper reinforced epoxy (CEM-3), phenolic-glass (G3), paper-phenolic (FR-1 or FR-2), polyester-glass (CEM-5), ABF (Ajinomoto Build-up Film), any other dielectric material, such as glass, or any combination thereof, such as can be used in printed circuit boards (PCBs).

In some embodiments, the substrate 110 can include a core 112 and multiple build-up layers, with each build-up layer including an interconnect level (i.e., a routing layer) for trace routing and a dielectric layer for electrically insulating laterally adjacent traces as well as adjacent interconnect levels (overlying and/or underlying). Conductive vias and solder connections can pass through the dielectric layer, such as to connect traces in different routing layers. For example, a routing layer 130 can be adjacent the core 112. The routing layer 130 can be separated from a routing layer 131 by a dielectric layer 132. In addition, a routing layer 134 can be adjacent an opposite side of the core 112. The routing layer 134 can be separated from a routing layer 135 by a dielectric layer 136. In the illustrated example, the routing layers 131, 134 are outer routing layers that are proximate outer surfaces of the substrate 110. Other routing layers, such as the routing layers 130, 134 may be referred to as inner routing layers. In some embodiments, the routing layer 130 can comprise an electrically conductive reference plane separated from the routing layer 131 by the dielectric material layer 132. Such a reference plane may be either a ground plane or a power plane, and in the one embodiment a ground plane is coupled to a ground reference maintained at an electrical ground potential. The substrate 110 illustrated in FIG. 1 is a 4L interconnect configuration, although other configurations are contemplated in accordance with the present technology.

In alternative embodiments, a coreless substrate including only build-up layers can be utilized in substantially the same manner as described herein in the context of a cored substrate. It should be recognized that a substrate can include any suitable number of routing layers having any suitable number of traces, and that any suitable number of vias can be utilized to electrically connect traces in different routing layers. In addition, the vias can have any suitable shape or configuration, such as a circular and/or non-circular (e.g., rectangular) cross-section.

As illustrated in FIG. 1, the substrate 110 can include electrically conductive elements 140, 141 at least partially disposed in adjacent routing layers 130, 131, respectively. The substrate 110 can also include an electrically conductive element 143 having portions 147a, 147b disposed in the routing layer 131, and an intermediate portion 147c disposed between the routing layers 130, 131, and therefore between the routing layer 131 and the core 112. In other words, the portions 147a, 147b of the conductive element 143 can be in the routing layer 131, and the intermediate portion 147c can be outside the routing layer 131 (e.g., offset from the routing layer 131, such as toward the core 112), and not in another routing layer but instead in a “sub-interconnect layer” or “pseudo layer” within the dielectric layer 132. The electrically conductive element 143 can include vias 148a, 148b to facilitate locating the intermediate portion 147c outside of the routing layer 131. A top view of the electrically conductive elements 141, 143 in the routing layer 131 is shown in FIG. 2, and a detail view of the routing layers 130, 131 is shown in FIG. 3.

A solder resist layer or mask 139 can be disposed at least partially over the dielectric material layer 132 and/or the electrically conductive elements 141, 143 for protection against oxidation and to prevent solder bridges from forming between closely spaced solder pads. The electronic component 120 can be operably coupled to one or more of the conductive elements 140, 141, 143, such as via the interconnect structures 121.

The thickness 113 of the dielectric layer 132 between adjacent routing layers 130, 131 is typically established based on design rules that account for factors such as dielectric raw material thickness, desired electrical properties of the signal trace, laser drilling capacity/tolerances, etc. Design rules exist to ensure that signal interference and cross-talk are limited to acceptable levels. The thickness 113 of the dielectric layer 132 between adjacent routing layers 130, 131 may typically be from about 40 μm to about 50 μm, although other dimensions are possible. The portions 147a, 147b of the electrically conductive element 143 are in the same routing layer 131 as the electrically conductive element 141, and the portion 147c of the electrically conductive element 143 is submerged or routed out of the routing layer 131 and into a sub-interconnect layer within the dielectric layer 132, in this case between the routing layers 130, 131. This sub-interconnect or pseudo layer routing of the portion 147c of the electrically conductive element 143 would typically violate the layer separation design rules mentioned above. However, in one aspect, a length 114 of the sub-interconnect portion 147c can be relatively short compared to an overall length of the channel (i.e., the length of the package 100 and the length of the PCB, which can be inches long). In one aspect, the length 114 of the sub-interconnect portion 147c (measured from the centers of the vias 148a, 148b) can be less than or equal to about 5 mm. In another aspect, the length 114 can be less than or equal to about 3 mm. In yet another aspect, the length 114 can be less than or equal to about 2 mm. The relatively short length 114 of the sub-interconnect portion 147c can provide minimal impact on signal interference and cross-talk, which can therefore be limited to acceptable levels even though the sub-interconnect portion 147c is separated from neighboring routing layers 130, 131 by distances 115, 116, respectively, that would normally violate layer separation design rules. The distances 115, 116 can be less than or equal to 25 μm parallel to the thickness 111 of the substrate 110, although other dimensions are possible. For example, the distances 115, 116 can be less than or equal to 20 μm, or less than or equal to 15 μm. In another aspect, the substrate 110 can include a low-K dielectric material (i.e., a material with a small dielectric constant relative to that of silicon dioxide) between the sub-interconnect portion 147c and the routing layer 130 and/or the routing layer 131 (indicated at 117a, 117b, respectively) to mitigate the risk of signal interference and cross-talk. In yet another aspect, as illustrated in FIG. 2 by an alternate sub-interconnect portion 147c′, the sub-interconnect portion 147c′ and the electrically conductive element 141 of the neighboring routing layer 131 can be routed such that they “cross” at an angle 118 that is about 90 degrees to cancel signal interference.

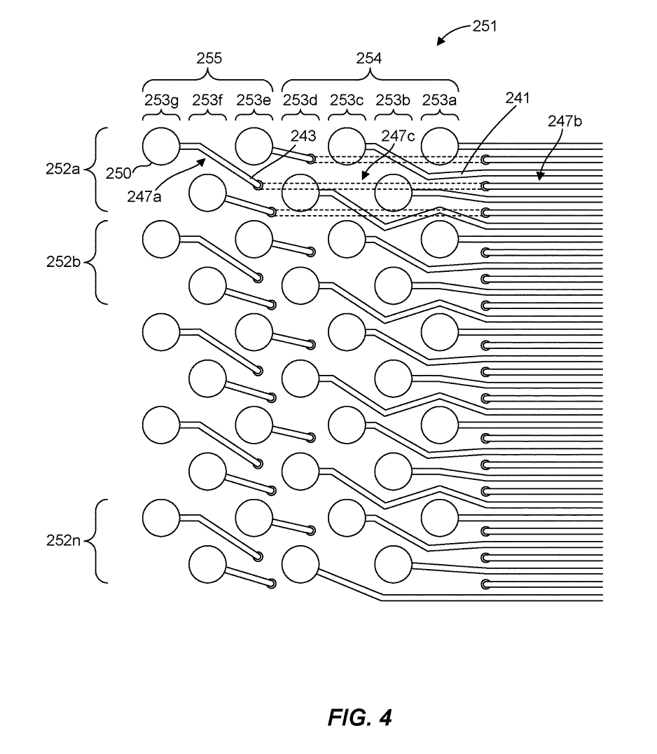

In one aspect, the principles disclosed herein can be applied to interface features and breakout regions to facilitate trace breakout in a minimal number of routing layers. FIG. 4 illustrates a top view of an array of interface features 250 and a trace breakout region 251 in accordance with an example of the present disclosure. The interface features 250 are portions of the electrically conductive elements (e.g., pads) that are configured to interface with interconnect structures, such as solder balls, solder bumps, copper bumps, gold studs or a combination of copper bumps and solder caps, for a flip-chip grid array (FCPGA, FCBGA, etc.), but embodiments of the present disclosure are applicable to any substrate assembly technologies, such as flip-chip-molded matrix array packages (FCMMAP), eWLB, embedded dies, bumpless assembly, etc.

The interface features 250 can be distributed within an area where an electronic component and a substrate connect. Various groups of the interface features 250 can be distributed in one or more repeating patterns. An instance of a group of interface features 250 that repeats may be termed a “spline”. The illustrated pattern includes seven interface features 250 that make up a spline 252a, and that pattern repeats itself to form additional splines (e.g., spline 252b through spline 252n), although a spline may include any suitable number of interface features. In some embodiments, the splines may mirror image at some point on the substrate. For example, spline 252a and spline 252n can be mirror images of each other. In the embodiment shown, however, the splines are oriented in the same direction. The interface features 250 can be arranged in any suitable pattern for any type of connection, such as signal input/output (I/O), power, ground, etc.

The interface features 250 may be considered as being arranged in rows 253a-g, with an outermost row (row 253a) being nearest the electronic component's edge, and one or more additional rows (such as row 253b through row 253g) each residing sequentially closer to the center or core of the electronic component. The interface features 250 in rows 253a-d may be considered in an outer portion 254 of the array or pattern, and the interface features 250 in rows 253e-g may be considered in an inner portion 255 of the array or pattern. The interface features 250 in the outer portion 254 can have escape routing (represented at 241) in the breakout region 251 that escapes in a common routing layer, such as an outer routing layer. The interface features 250 in the inner portion 255 can have escape routing (represented at 243) in the breakout region that escapes partially in the same routing layer as those of the outer portion 254 (e.g., portions 247a, 247b), and partially in a sub-interconnect or pseudo layer (e.g., portion 247c) as described herein. Even though the electrically conductive elements of the inner portion 255 are routed into a sub-interconnect layer out-of-plane with the routing layer utilized by the electrically conductive elements of the inner portion 254 for break out, the electrically conductive elements of the inner portion 255 may still utilize that routing layer for break out. The sub-interconnect portions of the inner portion 255 of the spline 252a are shown in broken lines to indicate where the sub-interconnect portions pass beneath the elements in the outer portion 254 of the spline 252a. The conductive element portions 247a, 247b of the inner portion 255 can be configured to reduce the risk of signal interference and cross-talk due to the presence of the portion 247c in a sub-interconnect layer proximate the conductive elements in the outer portion 254. For example, the portions 247a extending from the interface features 250 may be maximized in length in order to minimize the length of the sub-interconnect layer portion 247c and therefore mitigate potential signal interference and cross-talk risk with the conductive elements in the outer portion 254.

Thus, the sub-interconnect layer portions described herein can facilitate inner bump breakout in a package design. In some embodiments, the sub-interconnect layer portions can be disposed in a dielectric layer between the routing layers at a selected breakout region to facilitate breakout of the inner portion of signal I/O bumps without the need of a full build-up layer for breakout. Thus, a 6L (i.e., six layer) package design can be accomplished with 4L (i.e., four-layer) package stack-up without the need of a bump pattern change. In other words, a 4L package design can be implemented with a signal I/O bump pattern that is designed for 6L package, thus providing a relatively thin substrate that benefits from the signal I/O routing of a 6L package design. In addition to a cost savings for the substrate, the reduced layer count can provide a reduced or minimized substrate and package end-product thickness.

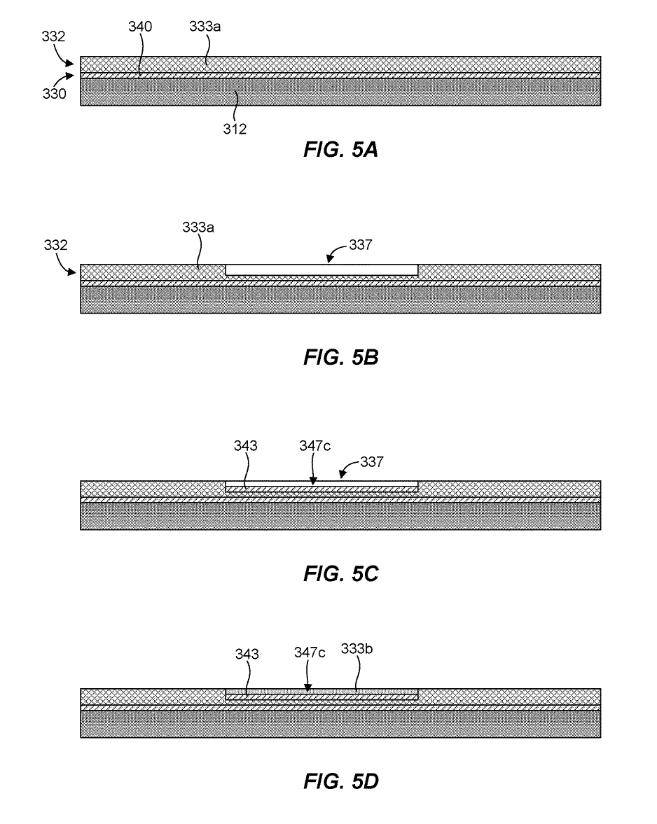

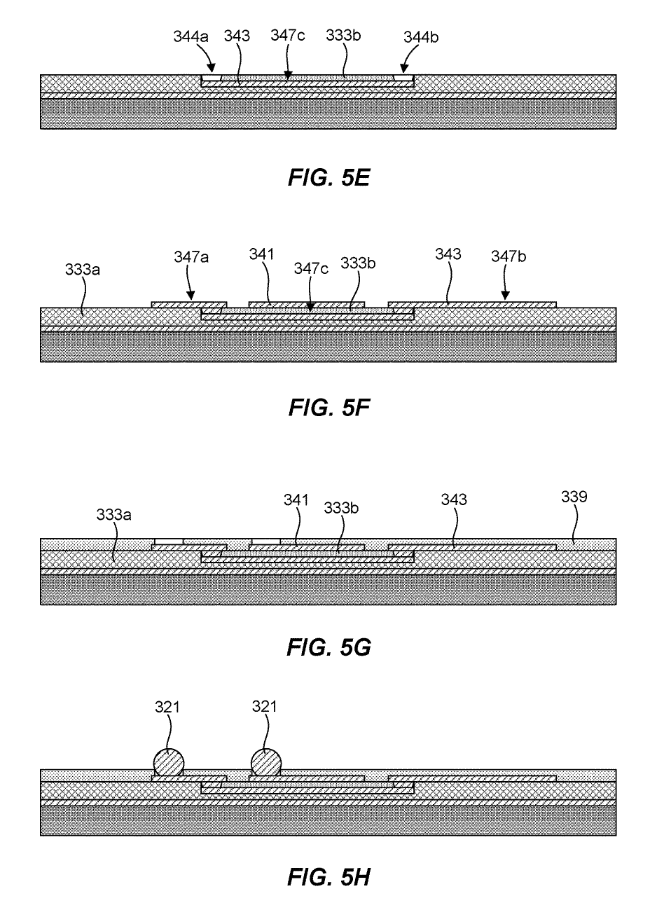

FIGS. 5A-5H illustrate aspects of an exemplary method or process for making a substrate as disclosed herein. FIG. 5A shows a routing layer 330 that includes an electrically conductive element 340. A dielectric layer 332 is disposed on the routing layer 330. The routing layer 330 in this embodiment is adjacent a core 312, although this need not be the case in other embodiments. FIG. 5B shows a recess 337 or trench that can be formed in a dielectric material portion 333a of the dielectric layer 332. The recess 337 can be formed by any suitable technique or process, such as drilling (e.g., laser drilling). As illustrated in FIG. 5C, a conductive material (e.g., copper) can be disposed in the recess 337 to form a sub-interconnect portion 347c of an electrically conductive element 343. A conductive material can be disposed in the recess 337 by any suitable technique or process, such as depositing the conductive material (e.g., plating and/or printing the conductive material). A dielectric material portion 333b can be disposed at least partially on the sub-interconnect portion 347c of the electrically conductive element 343, such as in the recess 337, as shown in FIG. 5D. This can be accomplished in any suitable manner, such as by depositing dielectric material, and then curing the dielectric material. FIG. 5E shows the formation of via openings 344a, 344b in the dielectric material portion 333b, which can expose portions of the sub-interconnect portion 347c of the electrically conductive element 343. The via openings 344a, 344b can be formed by any suitable technique or process, such as drilling (e.g., laser drilling) the dielectric material portion 333b, molding the dielectric material portion 333b, etc. As shown in FIG. 5F, portions 347a, 347b of the conductive element 343 can be formed at least partially on the dielectric material portion 333a and/or the dielectric material portion 333b, such that the portions 347a-c of the conductive element 343 are electrically coupled to one another. Conductive material can be disposed in the via openings 344a, 344b to electrically couple the portions 347a-c of the conductive element 343 to one another. A conductive element 341 can also be formed at least partially on the dielectric material portion 333b. The conductive element 341 and the portions 347a, 347b of the conductive element 343 can be formed simultaneously or at different times using the same or a different technique or process (e.g., plating and/or printing the conductive material). Any suitable technique or process may be used to deposit conductive material to form these conductive elements (e.g., plating and/or printing the conductive material). As FIG. 5G illustrates, a solder resist layer 339 can be formed at least partially on the dielectric material portions 333a, the dielectric material portion 333b, the conductive element 341, and/or the conductive element 343. The solder resist layer 339 can be formed by any suitable technique or process, such as silkscreening or spraying an epoxy or ink (e.g., liquid photoimageable solder mask (LPSM) ink) and/or laminating a dry film photoimageable solder mask (DFSM). Interconnect structures 321 (e.g., solder balls or bumps) can be disposed on exposed interface features (e.g., solder ball pads), as shown in FIG. 5H.

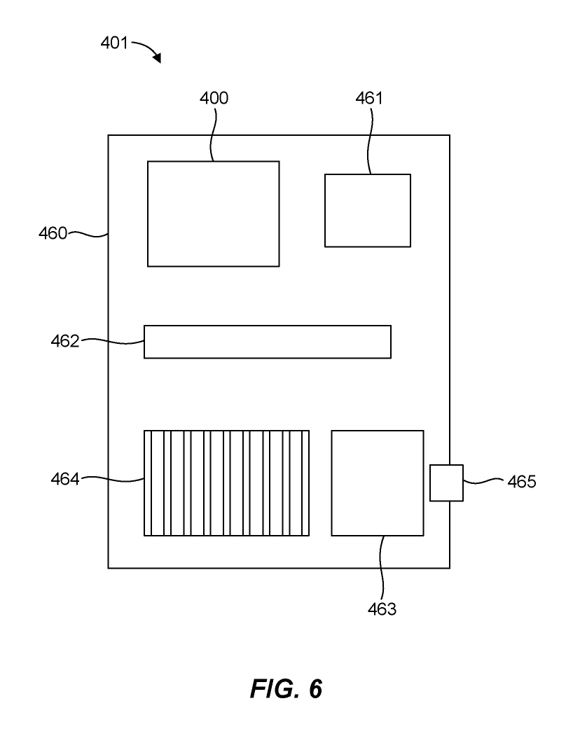

FIG. 6 illustrates an example computing system 401. The computing system 401 can include an electronic device package 400 as disclosed herein, coupled to a motherboard 460. In one aspect, the computing system 401 can also include a processor 461, a memory device 462, a radio 463, a heat sink 464, a port 465, a slot, or any other suitable device or component, which can be operably coupled to the motherboard 460. The computing system 401 can comprise any type of computing system, such as a desktop computer, a laptop computer, a tablet computer, a smartphone, a wearable device, a server, etc. Other embodiments need not include all of the features specified in FIG. 6, and may include alternative features not specified in FIG. 6.

### EXAMPLES

The following examples pertain to further embodiments.

In one example there is provided a substrate comprising a first conductive element at least partially disposed in a first routing layer, a second conductive element at least partially disposed in a second routing layer, wherein the first and second routing layers are adjacent routing layers, and a third conductive element having first and second portions disposed in the first routing layer, and an intermediate third portion disposed between the first and second routing layers.

In one example of a substrate, the intermediate portion has a length less than or equal to 5 mm.

In one example of a substrate, a distance between the intermediate portion and the first conductive element is less than or equal to 25 μm.

In one example of a substrate, the distance is parallel to a thickness of the substrate.

In one example of a substrate, a distance between the intermediate portion and the second conductive element is less than or equal to 25 μm.

In one example of a substrate, a distance between the first conductive element and the second conductive element is from about 40 μm to about 50 μm.

In one example, a substrate comprises a core, wherein the second routing layer is adjacent the core.

In one example, a substrate comprises at least one routing layer disposed on a side of the core opposite the first and second routing layers.

In one example of a substrate, the first routing layer is an outer routing layer.

In one example of a substrate, the first routing layer is proximate an outer surface of the substrate.

In one example of a substrate, the first conductive element and the third conductive element include ball pads that form at least a portion of a solder bump pattern.

In one example of a substrate, the solder bump pattern comprises a signal input/output (I/O) solder bump pattern.

In one example of a substrate, the ball pad of the first conductive element is in an outer portion of the solder bump pattern, and the ball pad of the third conductive element is in an inner portion of the solder bump pattern.

In one example of a substrate, the first conductive element comprises a plurality of first conductive elements and the third conductive element comprises a plurality of third conductive elements.

In one example there is provided a substrate comprising a first conductive element in a routing layer, and a second conductive element having first and second portions in the routing layer, and a third portion outside the routing layer and not in another routing layer.

In one example of a substrate, the third portion has a length less than or equal to 5 mm.

In one example of a substrate, a distance between the third portion and the first conductive element is less than or equal to 25 μm.

In one example of a substrate, the distance is parallel to a thickness of the substrate.

In one example, a substrate comprises a core, wherein the third portion is between the routing layer and the core.

In one example, a substrate comprises a second routing layer disposed on a side of the core opposite the first routing layer.

In one example of a substrate, the routing layer is an outer routing layer.

In one example of a substrate, the routing layer is proximate an outer surface of the substrate.

In one example of a substrate, the first conductive element and the second conductive element include ball pads that form at least a portion of a solder bump pattern.

In one example of a substrate, the solder bump pattern comprises a signal input/output (I/O) solder bump pattern.

In one example of a substrate, the ball pad of the first conductive element is in an outer portion of the solder bump pattern, and the ball pad of the second conductive element is in an inner portion of the solder bump pattern.

In one example of a substrate, the first conductive element comprises a plurality of first conductive elements and the second conductive element comprises a plurality of second conductive elements.

In one example there is provided an electronic device package comprising a substrate having a first conductive element at least partially disposed in a first routing layer, a second conductive element at least partially disposed in a second routing layer, wherein the first and second routing layers are adjacent routing layers, and a third conductive element having first and second portions disposed in the first routing layer, and an intermediate third portion disposed between the first and second routing layers, and an electronic component operably coupled to at least one of the first, second, and third conductive elements.

In one example of an electronic device package, the intermediate portion has a length less than or equal to 5 mm.

In one example of an electronic device package, a distance between the intermediate portion and the first conductive element is less than or equal to 25 μm.

In one example of an electronic device package, the distance is parallel to a thickness of the substrate.

In one example of an electronic device package, a distance between the intermediate portion and the second conductive element is less than or equal to 25 μm.

In one example of an electronic device package, a distance between the first conductive element and the second conductive element is from about 40 μm to about 50 μm.

In one example, an electronic device package comprises a core, wherein the second routing layer is adjacent the core.

In one example, an electronic device package comprises at least one routing layer disposed on a side of the core opposite the first and second routing layers.

In one example of an electronic device package, the first routing layer is an outer routing layer.

In one example of an electronic device package, the first routing layer is proximate an outer surface of the substrate.

In one example of an electronic device package, the first conductive element and the third conductive element include ball pads that form at least a portion of a solder bump pattern.

In one example of an electronic device package, the solder bump pattern comprises a signal input/output (I/O) solder bump pattern.

In one example of an electronic device package, the ball pad of the first conductive element is in an outer portion of the solder bump pattern, and the ball pad of the third conductive element is in an inner portion of the solder bump pattern.

In one example of an electronic device package, the first conductive element comprises a plurality of first conductive elements and the third conductive element comprises a plurality of third conductive elements.

In one example of an electronic device package, the electronic component comprises a die, a chip, a processor, computer memory, a platform controller hub, or a combination thereof.

In one example there is provided an electronic device package comprising a substrate including a first conductive element in a routing layer, and a second conductive element having first and second portions in the routing layer, and a third portion outside the routing layer and not in another routing layer, and an electronic component operably coupled to at least one of the first and second conductive elements.

In one example of an electronic device package, the third portion has a length less than or equal to 5 mm.

In one example of an electronic device package, a distance between the third portion and the first conductive element is less than or equal to 25 μm.

In one example of an electronic device package, the distance is parallel to a thickness of the substrate.

In one example, an electronic device package comprises a core, wherein the third portion is between the routing layer and the core.

In one example, an electronic device package comprises a second routing layer disposed on a side of the core opposite the first routing layer.

In one example of an electronic device package, the routing layer is an outer routing layer.

In one example of an electronic device package, the routing layer is proximate an outer surface of the substrate.

In one example of an electronic device package, the first conductive element and the second conductive element include ball pads that form at least a portion of a solder bump pattern.

In one example of an electronic device package, the solder bump pattern comprises a signal input/output (I/O) solder bump pattern.

In one example of an electronic device package, the ball pad of the first conductive element is in an outer portion of the solder bump pattern, and the ball pad of the second conductive element is in an inner portion of the solder bump pattern.

In one example of an electronic device package, the first conductive element comprises a plurality of first conductive elements and the second conductive element comprises a plurality of second conductive elements.

In one example of an electronic device package, the electronic component comprises a die, a chip, a processor, computer memory, a platform controller hub, or a combination thereof.

In one example there is provided a computing system comprising a motherboard, and an electronic device package operably coupled to the motherboard, the electronic device package including a substrate having a first conductive element at least partially disposed in a first routing layer, a second conductive element at least partially disposed in a second routing layer, wherein the first and second routing layers are adjacent routing layers, and a third conductive element having first and second portions disposed in the first routing layer, and an intermediate third portion disposed between the first and second routing layers, and an electronic component operably coupled to at least one of the first, second, and third conductive elements.

In one example of a computing system, the computing system comprises a desktop computer, a laptop, a tablet, a smartphone, a wearable device, a server, or a combination thereof.

In one example of a computing system, the computing system further comprises a processor, a memory device, a heat sink, a radio, a slot, a port, or a combination thereof operably coupled to the motherboard.

In one example there is provided a method for making a substrate comprising forming a recess in a first dielectric material portion, disposing conductive material in the recess to form a first portion of a first conductive element, disposing a second dielectric material portion at least partially on the first portion of the first conductive element, forming second and third portions of the first conductive element at least partially on one or more of the first dielectric material portion and the second dielectric material portion, wherein the first, second, and third portions of the first conductive element are electrically coupled to one another, and forming a second conductive element at least partially on the second dielectric material portion.

In one example of a method for making a substrate, forming the recess comprises drilling.

In one example of a method for making a substrate, drilling comprises laser drilling.

In one example of a method for making a substrate, disposing conductive material comprises depositing conductive material.

In one example of a method for making a substrate, depositing conductive material comprises plating, printing, or a combination thereof.

In one example of a method for making a substrate, disposing the second dielectric material portion comprises depositing dielectric material, and curing the dielectric material.

In one example, a method for making a substrate comprises one or more via openings in the second dielectric material.

In one example of a method for making a substrate, forming one or more via openings comprises drilling.

In one example of a method for making a substrate, drilling comprises laser drilling.

In one example of a method for making a substrate, forming second and third portions of the first conductive element comprises disposing conductive material in the one or more via openings such that the first, second, and third portions of the first conductive element are electrically coupled to one another.

In one example of a method for making a substrate, forming second and third portions of the first conductive element comprises depositing conductive material.

In one example of a method for making a substrate, depositing conductive material comprises plating, printing, or a combination thereof.

In one example of a method for making a substrate, forming the second conductive element comprises depositing conductive material.

In one example of a method for making a substrate, depositing conductive material comprises plating, printing, or a combination thereof.

In one example, a method for making a substrate comprises forming a solder resist layer at least partially on the first dielectric material portion and the second dielectric material portion.

In one example of a method for making a substrate, the third portion has a length less than or equal to 5 mm.

In one example of a method for making a substrate, a distance between the third portion and the second conductive element is less than or equal to 25 μm.

In one example of a method for making a substrate, the distance is parallel to a thickness of the substrate.

In one example of a method for making a substrate, the first conductive element and the second conductive element include ball pads that form at least a portion of a solder bump pattern.

In one example of a method for making a substrate, the solder bump pattern comprises a signal input/output (I/O) solder bump pattern.

In one example of a method for making a substrate, the ball pad of the first conductive element is in an inner portion of the solder bump pattern, and the ball pad of the second conductive element is in an outer portion of the solder bump pattern.

Circuitry used in electronic components or devices (e.g. a die) of an electronic device package can include hardware, firmware, program code, executable code, computer instructions, and/or software. Electronic components and devices can include a non-transitory computer readable storage medium which can be a computer readable storage medium that does not include signal. In the case of program code execution on programmable computers, the computing devices recited herein may include a processor, a storage medium readable by the processor (including volatile and non-volatile memory and/or storage elements), at least one input device, and at least one output device. Volatile and non-volatile memory and/or storage elements may be a RAM, EPROM, flash drive, optical drive, magnetic hard drive, solid state drive, or other medium for storing electronic data. Node and wireless devices may also include a transceiver module, a counter module, a processing module, and/or a clock module or timer module. One or more programs that may implement or utilize any techniques described herein may use an application programming interface (API), reusable controls, and the like. Such programs may be implemented in a high level procedural or object oriented programming language to communicate with a computer system. However, the program(s) may be implemented in assembly or machine language, if desired. In any case, the language may be a compiled or interpreted language, and combined with hardware implementations.

While the forgoing examples are illustrative of the specific embodiments in one or more particular applications, it will be apparent to those of ordinary skill in the art that numerous modifications in form, usage and details of implementation can be made without departing from the principles and concepts articulated herein.

1. A substrate, comprising:
a first conductive element at least partially disposed in a first routing layer;
a second conductive element at least partially disposed in a second routing layer, wherein the first and second routing layers are adjacent routing layers; and
a third conductive element having first and second portions disposed in the first routing layer, and an intermediate third portion disposed between the first and second routing layers.

2. The substrate of claim 1, wherein the intermediate portion has a length less than or equal to 5 mm.

3. The substrate of claim 1, wherein a distance between the intermediate portion and the first conductive element is less than or equal to 25 μm.

4. The substrate of claim 3, wherein the distance is parallel to a thickness of the substrate.

5. The substrate of claim 1, wherein a distance between the intermediate portion and the second conductive element is less than or equal to 25 μm.

6. The substrate of claim 1, wherein a distance between the first conductive element and the second conductive element is from about 40 μm to about 50 μm.

7. The substrate of claim 1, further comprising a core, wherein the second routing layer is adjacent the core.

8. The substrate of claim 7, further comprising at least one routing layer disposed on a side of the core opposite the first and second routing layers.

9. The substrate of claim 1, wherein the first routing layer is an outer routing layer.

10. The substrate of claim 1, wherein the first routing layer is proximate an outer surface of the substrate.

11. The substrate of claim 1, wherein the first conductive element and the third conductive element include ball pads that form at least a portion of a solder bump pattern.

12. The substrate of claim 11, wherein the solder bump pattern comprises a signal input/output (I/O) solder bump pattern.

13. The substrate of claim 11, wherein the ball pad of the first conductive element is in an outer portion of the solder bump pattern, and the ball pad of the third conductive element is in an inner portion of the solder bump pattern.

14. The substrate of claim 1, wherein the first conductive element comprises a plurality of first conductive elements and the third conductive element comprises a plurality of third conductive elements.

15. An electronic device package, comprising:
a substrate having
a first conductive element at least partially disposed in a first routing layer,
a second conductive element at least partially disposed in a second routing layer,
wherein the first and second routing layers are adjacent routing layers, and
a third conductive element having first and second portions disposed in the first routing layer, and an intermediate third portion disposed between the first and second routing layers; and
an electronic component operably coupled to at least one of the first, second, and third conductive elements.

16. The electronic device package of claim 15, wherein the intermediate portion has a length less than or equal to 5 mm.

17. The electronic device package of claim 15, wherein a distance between the intermediate portion and the first conductive element is less than or equal to 25 μm.

18. The electronic device package of claim 15, wherein a distance between the intermediate portion and the second conductive element is less than or equal to 25 μm.

19. The electronic device package of claim 15, wherein a distance between the first conductive element and the second conductive element is from about 40 μm to about 50 μm.

20. The electronic device package of claim 15, further comprising a core, wherein the second routing layer is adjacent the core.

21. The electronic device package of claim 15, wherein the first routing layer is an outer routing layer.

22. The electronic device package of claim 15, wherein the first routing layer is proximate an outer surface of the substrate.

23. The electronic device package of claim 15, wherein the first conductive element and the third conductive element include ball pads that form at least a portion of a solder bump pattern.

24. The electronic device package of claim 15, wherein the first conductive element comprises a plurality of first conductive elements and the third conductive element comprises a plurality of third conductive elements.

25. The electronic device package of claim 15, wherein the electronic component comprises a die, a chip, a processor, computer memory, a platform controller hub, or a combination thereof.

26. A method for making a substrate, comprising:
forming a recess in a first dielectric material portion;
disposing conductive material in the recess to form a first portion of a first conductive element;
disposing a second dielectric material portion at least partially on the first portion of the first conductive element;
forming second and third portions of the first conductive element at least partially on one or more of the first dielectric material portion and the second dielectric material portion, wherein the first, second, and third portions of the first conductive element are electrically coupled to one another; and
forming a second conductive element at least partially on the second dielectric material portion.

27. The method of claim 26, further comprising forming one or more via openings in the second dielectric material.

28. The method of claim 27, wherein forming one or more via openings comprises drilling.

29. The method of claim 28, wherein drilling comprises laser drilling.
